(19) United States
(12) Patent Application Publication
(10) Pub. No.: US 2018/0076803 A1
(43) Pub. Date: Mar. 15, 2018

(54) CLOCK-DISTRIBUTION DEVICE OF IC AND METHOD FOR ARRANGING CLOCK-DISTRIBUTION DEVICE

(71) Applicant: MediaTek Singapore Pte. Ltd., Singapore (SG)

(72) Inventors: Lan-Sin LIAU, Buangkok (SG); Jiaying CHEN, Singapore (SG)

(21) Appl. No.: 15/816,920

(22) Filed: Nov. 17, 2017

Related U.S. Application Data
(63) Continuation-in-part of application No. 14/828,778, filed on Aug. 18, 2015.
(60) Provisional application No. 62/089,990, filed on Dec. 10, 2014.

(51) Int. Cl. H03K 5/05; H03K 5/135; H03K 5/15

(52) U.S. Cl. CPC H03K 5/05; H03K 5/15; H03K 5/135

(57) ABSTRACT

A method for arranging a clock-distribution device of an IC is provided. An initial placement of the IC is obtained. The initial placement includes a first portion corresponding to a clock-distribution device, a second portion corresponding to a plurality of modules, and a third portion corresponding to a clock-generation device. The clock-distribution device distributes a plurality of first clock signals to the modules according to a second clock signal from the clock-generation device. The first portion is selected from the initial placement. Clocks within the selected first portion are distributed to obtain a fourth portion of the clock-distribution device. The fourth portion is placed in the initial placement to replace the first portion and to obtain a final placement of the IC. Each module has an input port corresponding to the individual first clock signal, and the clock-generation device has an output port corresponding to the second clock signal.

### CROSS REFERENCE TO RELATED APPLICATIONS

This application is a Continuation-In-Part of pending U.S. patent application Ser. No. 14/828,778, filed Aug. 18, 2015 and entitled “clock-distribution device and clock-distribution method”, which claims the benefit of Provisional Application No. 62/089,990, filed on Dec. 10, 2014, the entirety of which are incorporated by reference herein.

### BACKGROUND OF THE INVENTION

### Field of the Invention

The present inventive concept relates to a clock-distribution device. More particularly, the inventive concept relates to a clock-distribution device with a clock mesh and mesh drivers.

### Description of the Related Art

In order to access and use semiconductor devices properly, it is necessary to distribute clock signals to its parallel sequential elements at approximately the same time within the semiconductor devices. For example, the parallel sequential elements could include registers, flip-flops, latches and memory. When clock signals arrive at these parallel sequential elements at different times, clock skew may occur. Accordingly, the clock skew could cause a variety of problems including setup and hold violations. The integrity of data transmitted along the semiconductor device could be affected, and the performance of the semiconductor device could deteriorate. Therefore, an efficient clock-distribution device and an efficient clock-distribution method are needed to reduce clock skew and prevent performance deterioration.

### BRIEF SUMMARY OF THE INVENTION

A method for arranging a clock-distribution device of an integrated circuit (IC) is provided. An initial placement of the IC is obtained, wherein the initial placement comprises a first portion corresponding to a clock-distribution device, a second portion corresponding to a plurality of modules, and a third portion corresponding to a clock-generation device, wherein the clock-distribution device is configured to distribute a plurality of first clock signals to the modules according to a second clock signal from the clock-generation device. The first portion is selected from the initial placement. Clocks within the selected first portion are distributed to obtain a fourth portion of the clock-distribution device. The fourth portion is placed in the initial placement to replace the first portion and to obtain a final placement of the IC. Each of the modules has an input port corresponding to the individual first clock signal, and the clock-generation device has an output port corresponding to the second clock signal.

Furthermore, a method for arranging a clock-distribution device of an integrated circuit (IC) is provided. An initial placement of the IC is obtained, wherein the initial placement comprises a profile of a clock-distribution device, a first layout of a plurality of modules, and a second layout of a clock-generation device, wherein the clock-distribution device is configured to distribute a plurality of first clock signals to the modules according to a second clock signal from the clock-generation device. The profile of a clock-distribution device is cut out from the initial placement. Clocks within the clock-distribution device are distributed to arrange a clock mesh and at least one mesh driver in the clock-distribution device, to obtain a third layout of the clock-distribution device. The first layout of the modules, the second layout of the clock-generation device, and the third layout of the clock-distribution device are integrated to obtain a final placement of the IC. Each of the modules has an input port corresponding to the individual first clock signal, and the clock-generation device has an output port corresponding to the second clock signal.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic diagram of the clock-distribution device according to the present invention;

FIG. 2 is another schematic diagram of the clock-distribution device according to the present invention;

FIG. 3 is another schematic diagram of the clock-distribution device according to the present invention;

FIG. 4 is a schematic diagram of the clock-distribution device, the clock-generation device and registers according to the present invention;

FIG. 5A to FIG. 5D are schematic diagrams illustrating the arrangements of the clock-distribution device according to the present invention;

FIG. 6 is a flow chart illustrating the clock-distribution method according to the present invention;

FIG. 7 shows a flow chart illustrating a hierarchical design process of an integrated circuit (IC) according to an embodiment of the invention;

FIG. 8 shows a method for arranging a clock-distribution device of an integrated circuit (IC) according to an embodiment of the invention, wherein the method of FIG. 8 is performed by a computer capable of operating an electronic design automation (EDA) tool;

FIG. 9A shows an example illustrating an initial placement of an IC obtained in step S810 of the method of FIG. 8;

FIG. 9B shows an example illustrating a final placement and the routing paths of the IC obtained in step S830 of the method of FIG. 8; and

FIG. 10 shows a computer system according to an embodiment of the invention.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF THE INVENTION

The following description is of the best-contemplated operation of carrying out the invention. This description is made for the purpose of illustrating the general principles of the invention and should not be taken in a limiting sense. Certain terms and figures are used throughout the description and following claims to refer to particular components. As one skilled in the art will appreciate, manufacturers may refer to a component by different names. This document does not intend to distinguish between components that differ in name but not function. The terms “component”, “system” and “device” used in the present invention could be the entity relating to the computer which is hardware, software, or a combination of hardware and software. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

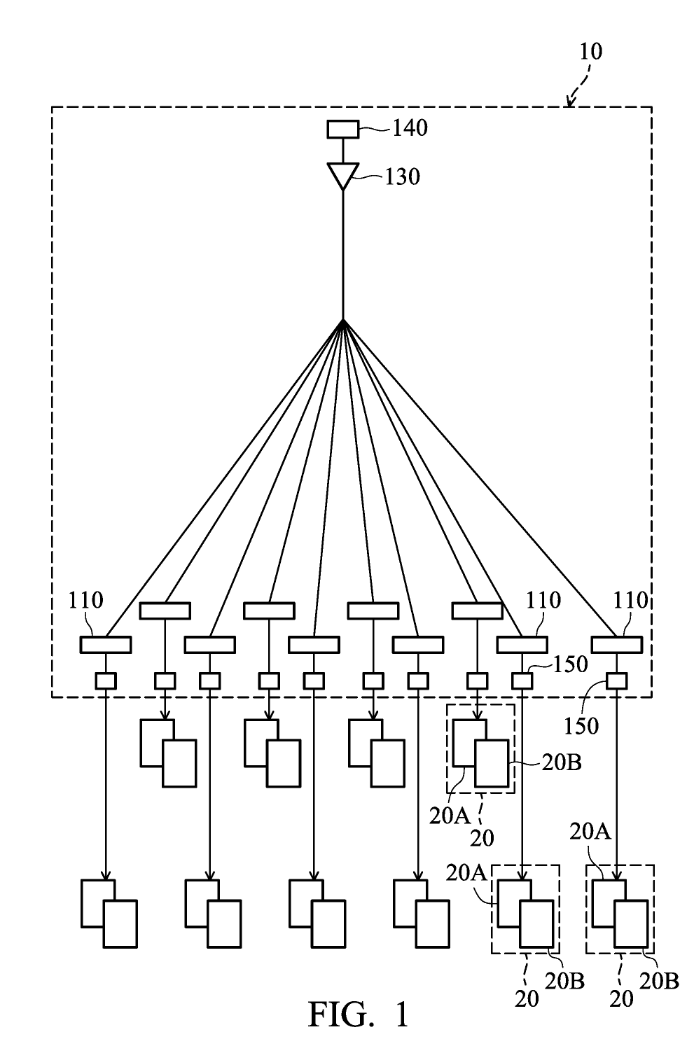

FIG. 1 is a schematic diagram of the clock-distribution device 10 according to the present invention. The clock-distribution device 10 could be arranged within a semiconductor device and utilized for a processor. The processor could include a digital signal processor (DSP), a microcontroller (MCU), a central-processing unit (CPU) or a plurality of parallel processors relating the parallel processing environment to implement the operating system (OS), firmware, driver and/or other applications of an electronic device. The electronic device mentioned above could be a mobile electronic device such as a cell phone, a tablet computer, a laptop computer or a PDA, or could it be an electronic device such as a desktop computer or a server.

The clock-distribution device 10 and a plurality of registers 20 are illustrated in FIG. 1. The clock-distribution device 10 is utilized for dividing a clock signal into a plurality of clock signals for the registers 20. The register 20 could include more than one register such as the sub-register 20A and the sub-register 20B. The number and the type of the register 20 are not limited. In one embodiment, the clock-distribution device 10 includes a buffer 130, an input port 140, at least one clock gate 110 and at least one output port 150 as shown in FIG. 1. The input port 140 is utilized to receive a clock signal. The buffer 130 is coupled between the input port 140 and the clock gates 110 to transmit the clock signal from the input port 140 to each of the clock gates 110. Each of the clock gates 110 connects to each of the respective output ports 150. Therefore, the clock signal could be transmitted from the clock-distribution device 10 to the registers 20 through the output ports 150.

In the embodiment as shown in FIG. 1, the clock signals are distributed by the clock-distribution device 10 and provided for the registers 20. However, the clock signals could not be received by each of the registers 20 at the same time, which result in the clock skew for the clock-distribution device 10 and the registers 20. The performance of the clock-distribution device 10 and the registers 20 may be degraded accordingly. In addition, the clock-distribution device 10 is a flattened design, which means that the clock signal is directly transmitted from the buffer 130 to the clock gates 150. There, it consumes time (for example, 1 hour) to generate output files such as SPEF files and netlist files.

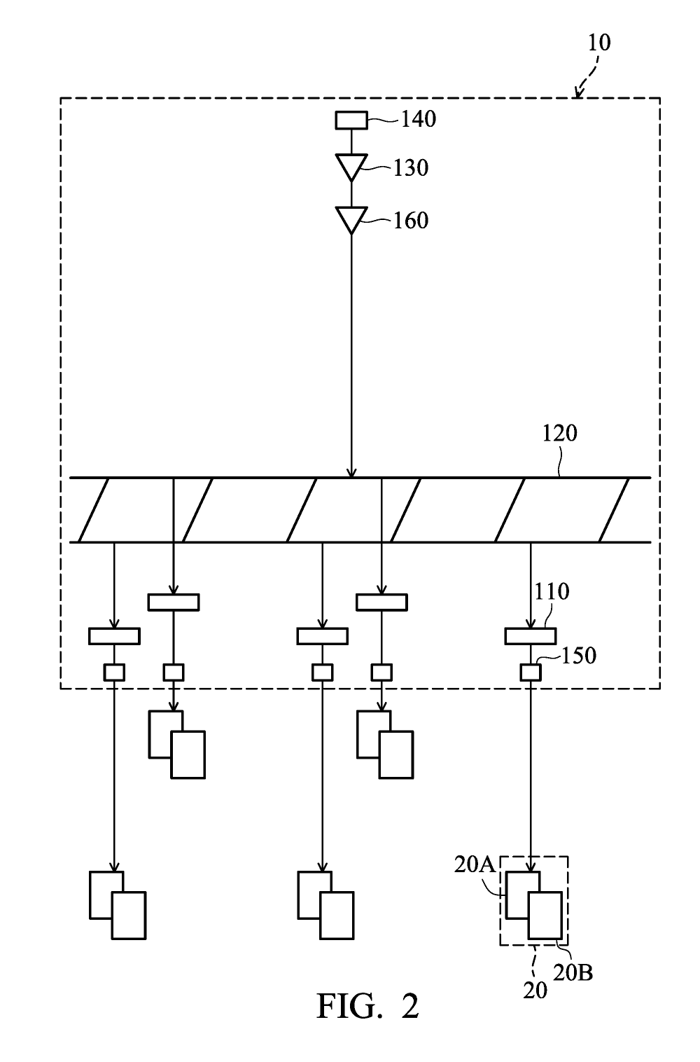

FIG. 2 is another schematic diagram of the clock-distribution device 10 according to the present invention. As shown in FIG. 2, the clock-distribution device 10 includes at least one buffer 130, an input port 140, a clock mesh 120, at least one clock gate 110, at least one mesh driver 160 and at least one output port 150. The input port 140 is utilized to receive a clock signal. The buffer 130 is coupled between the input port 140 and the mesh drivers 160 to transmit the clock signal from the input port 140 to the mesh drivers 160. In addition, the mesh drivers 160 are coupled between the buffer 130 and the clock mesh 120 to drive the clock mesh 120.

In one embodiment, the clock mesh 120 is arranged between the clock gates 110 and the mesh drivers 160 to distribute the clock signals to the clock gates 110 uniformly. In other words, the clock signals arrive at each of the clock gates 110 at approximately the same time. Compared with the embodiment of FIG. 1, clock skew could be reduced due to the arrangement of the clock mesh 120 as shown in FIG. 2. It should be noted that the clock mesh 120 is laid uniformly across the clock gates 110 to reduce the variation of distance and the variation of the RC delay between the clock mesh 120 and the clock gates 110. As such, the clock signals could be received by each of the clock gates almost at the same time to reduce the clock skew. Furthermore, each of the clock gates 110 connects to each of the respective output ports 150. Therefore, the clock signals could be distributed by the clock-distribution device 10 and transmitted to each of the registers 20.

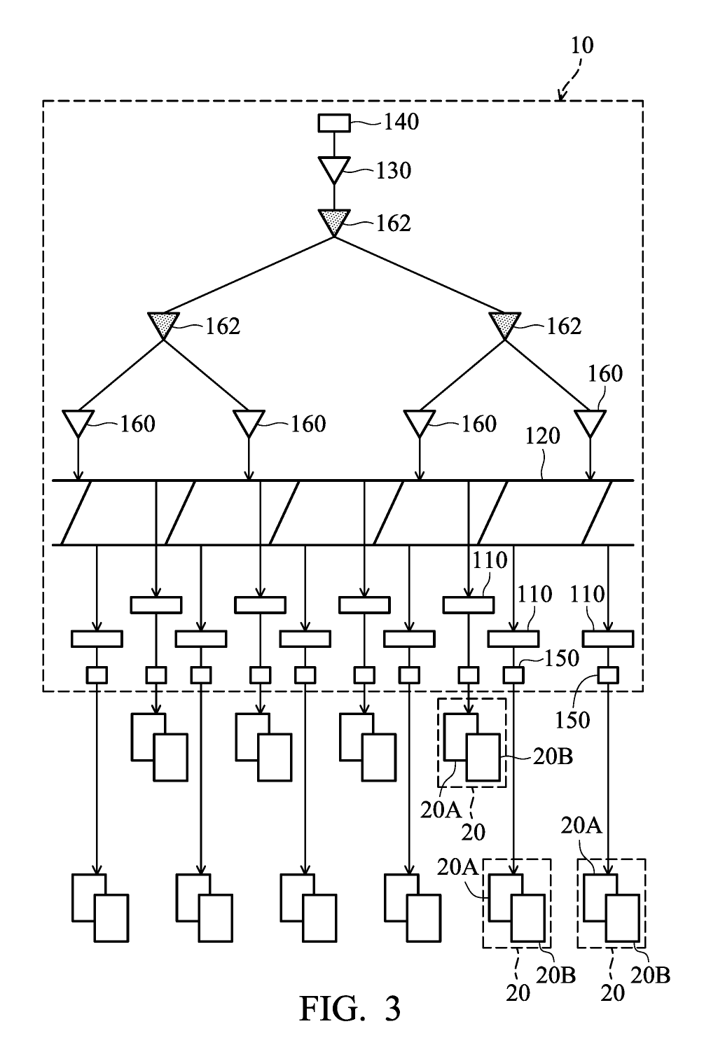

FIG. 3 is another schematic diagram of the clock-distribution device 10 according to the present invention. As shown in FIG. 3, the clock-distribution device 10 includes at least one buffer 130, an input port 140, a clock mesh 120, at least one clock gate 110, at least one mesh driver 160, at least one pre-mesh drivers and at least one output port 150. The input port 140 is utilized to receive a clock signal. The buffer 130 is coupled between the input port 140 and the pre-mesh drivers 162 to transmit the clock signal from the input port 140 to the pre-mesh drivers 162. Specifically, the pre-mesh drivers 162 are coupled between the buffer 130 and the mesh drivers 160 to drive the mesh drivers 160. The mesh drivers 160 are coupled between the pre-mesh drivers 162 and the clock mesh 120 to drive the clock mesh 120. Afterwards, the clock mesh 120 is utilized to uniformly distribute the clock signals to the clock gates 110.

It should be noted that the number of registers 20 in FIG. 3 is higher than the number of registers 20 in FIG. 2, which means that the loading for the clock-distribution device 10 of FIG. 3 is heavier than the loading for the clock-distribution device 10 of FIG. 2. Therefore, compared with the embodiment of FIG. 2, more clock gates 110 are arranged for transmitting the clock signals, and more mesh drivers 160 and pre-mesh drivers 162 are arranged to drive the clock mesh 120 for distributing the clock signals. In other words, the number of clock gates 110 is proportional to the number of registers 20. The number of clock gates 110 should be increased when the number of registers 20 increases. In addition, the number of the mesh drivers 160 and the pre-mesh drivers 162 is also determined by the number of registers 20. The number of the mesh drivers 160 and the pre-mesh drivers 162 should be increased correspondingly when the number of registers 20 increases.

In another embodiment, the number of mesh drivers 160 and pre-mesh drivers 162 is also determined by the transition of the clock signal. The clock signal includes two different states, and it switches between the two states alternatively. The transition of clock signal indicates the rate and speed it switches between the two different states. More specifically, the number of mesh drivers 160 and the pre-mesh drivers 162 is proportional to the transition of the clock signals. When the transition of the clock signals increases, more driving capacity will be needed corresponding to the high-speed transition. Therefore, the number of mesh drivers 160 and pre-mesh drivers 162 should be increased for obtaining a high driving capacity.

Furthermore, when the loading of the clock-distribution device 10 increases, the transition of the clock signals will be decreased. When the transition of the clock signal is pre-determined and fixed due to the design requirement of the semiconductor device, the loading of the clock-distribution device 10 should also be arranged within the certain range and limitation. Therefore, the configuration of the clock mesh 120 and the arrangement of the mesh drivers 160 and pre-mesh drivers 162 could be determined according to the synergy of both the transition of the clock signal and the loading of the clock-distribution device 10.

In the embodiment of FIG. 3, the clock mesh 120 is laid uniformly across the clock gates 110 to reduce the variation of distance and the variation of the RC delay between the clock mesh 120 and the clock gates 110. As such, the clock signals could be received by each of the clock gates 110 at almost the same time to reduce the clock skew. Compared with the embodiments of top-level design where the registers 20, the clock-generation device 30 and the clock gates 110 are flattened design, less time is required to generate output files by the clock-distribution device 10 of FIG. 3.

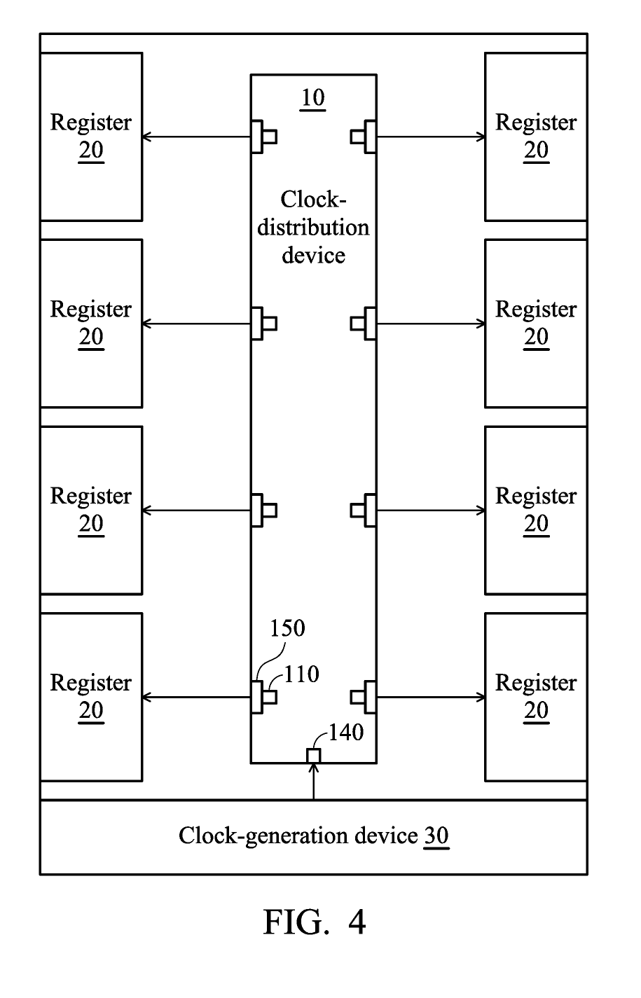

FIG. 4 is a schematic diagram of the clock-distribution device 10, the clock-generation device 30 and registers 20 according to the present invention. The clock signal is generated by the clock-generation device 30 and transmitted to the clock-distribution device 10 through the input port 140. Afterwards, the clock-distribution device 10 divides the clock signal into a plurality of clock signals and distributes them uniformly to the registers 20. It should be noted that the configuration and shape of the clock-distribution device are determined based on the arrangement of the registers 20 surrounding the clock-distribution device 10. For example, the shape of the clock-distribution device 10 is rectangular as shown in FIG. 4. The shape of the clock-distribution device 10 could be adjusted corresponding to the number of registers 20 and the arrangement positions of the registers 20.

Regarding the configuration of the clock-distribution device 10, the arrangement of the input port 140, the clock gates 110 and the output ports 150 of the clock-distribution device 10 are also determined in accordance with the number and arrangement positions of the registers 20 and the clock-generation device 30. Accordingly, the clock mesh 120 and it related mesh drivers 160 and pre-mesh drivers 162 are also determined in accordance with the arrangement and positions of the registers 20 and the clock-generation device 30. For example, when lots of registers 20 are arranged, a great number of mesh-drivers 160 and pre-mesh drivers 162 will be needed for the clock-distribution device 10. In order to drive the clock mesh 120 properly and efficiently, the mesh-drivers 160 and pre-mesh drivers 162 could be arranged in a tree-structure with multiple points.

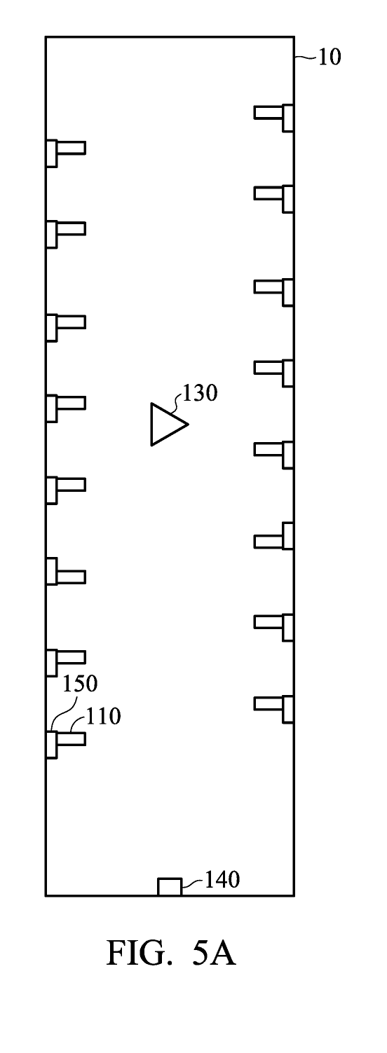

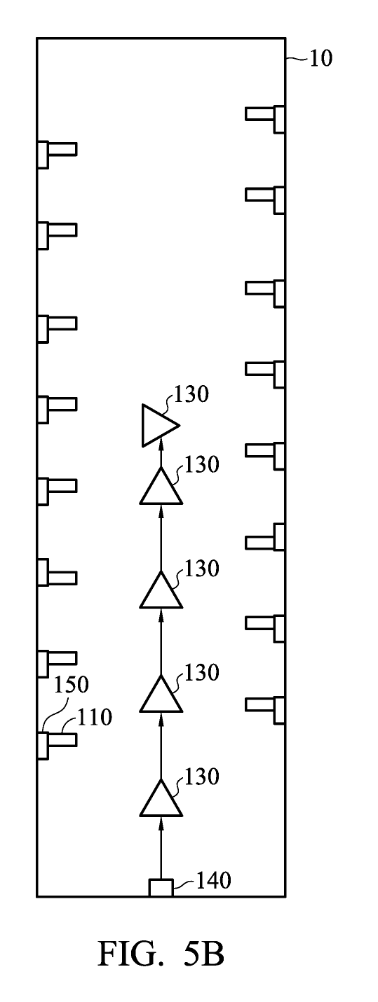

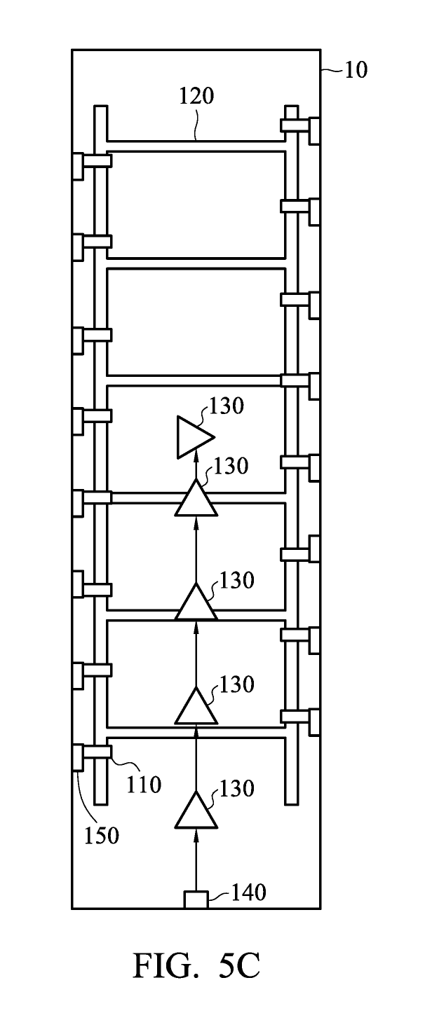

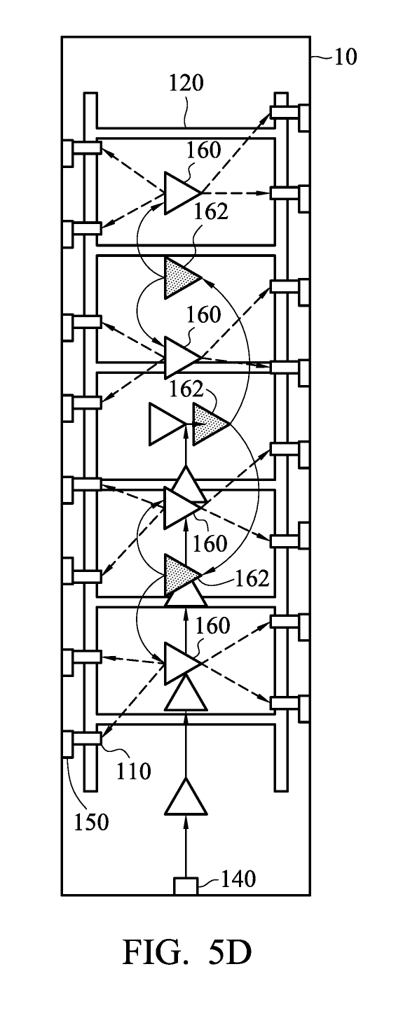

FIG. 5A to FIG. 5D are schematic diagrams illustrating the arrangements of the clock-distribution device 10 according to the present invention. As shown in FIG. 5A, the clock gates 110, buffer 130, the input port 140 and the output ports 150 are arranged in accordance with the registers 20 and the clock-generation device 30. Each of the clock gates is placed with each of the output ports 150, which means that the clock gates 110 are arranged to connect to the output ports 150 for transmitting the clock signals between the clock-distribution device 10 and the register 20. Afterwards, in the embodiment of FIG. 5B, a buffer tree consisting of several buffers 130 is arranged so that the clock signal could be transmitted from the input port 140 to the buffer 130. It should be noted the number of buffers 130 could be adjusted according to the configuration of the clock-distribution device 10. Afterwards, in the embodiment of FIG. 5C, the clock mesh 120 is arranged for uniformly distributing the clock signals to each of the clock gates 110. Afterwards, in the embodiment of FIG. 5D, the mesh drivers 160 and the pre-mesh drivers 162 are placed to drive the clock mesh 120.

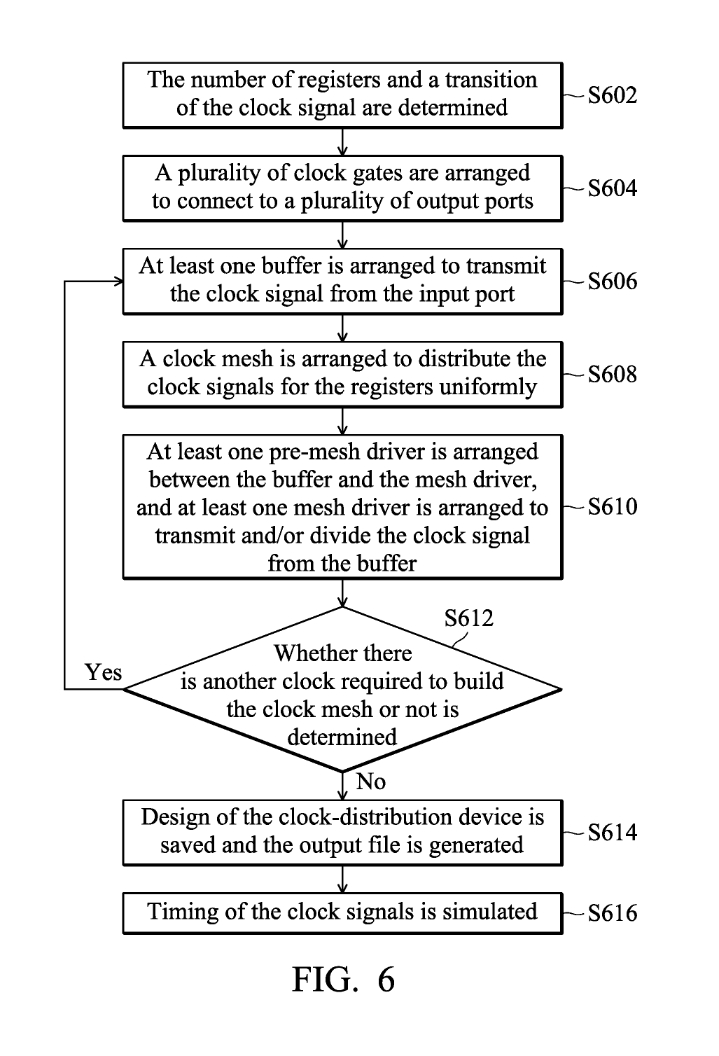

FIG. 6 is a flow chart illustrating the clock-distribution method according to the present invention. In step S602, the number of registers 20 and the transition of the clock signal are determined. Afterwards, in step S604, a plurality of clock gates 110 are arranged to connect to a plurality of output ports 150. In step S606, at least one buffer 130 is arranged to transmit the clock signal from an input port 140. Afterwards, a clock mesh 120 is arranged to distribute the clock signals for the registers 20 uniformly as shown in step S608. In step S610, at least one pre-mesh driver 162 is arranged between the buffer 130 and the mesh driver 160, and at least one mesh driver 160 is arranged to transmit and/or divide the clock signal from the buffer 130.

In step S612, whether there is another clock required to build the clock mesh 120 or not is determined. If there is another clock required to build the clock mesh, step S606 to step S610 will be executed again. If there is not another clock required to build the clock mesh, once the clock routing for the clock mesh 120, the pre-mesh drivers 162 and the mesh drivers 160 is completed step S614 is executed that the design of the clock-distribution device 10 is saved and the output file is generated. Afterwards, in step S616, timing of the clock signals is simulated.

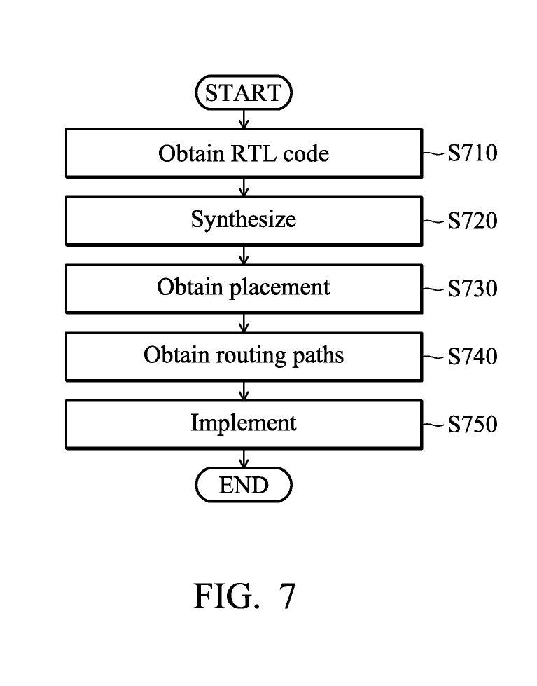

FIG. 7 shows a flow chart illustrating a hierarchical design process of an integrated circuit (IC) according to an embodiment of the invention. First, in step S710, a register-transfer-level (RTL) code describing the function performed by the IC is obtained. Next, in step S720, the RTL code is synthesized to generate the netlist regarding the gates for the IC. Next, in step S730, a placement procedure is performed to generate a placement of the gates within a chip area of the IC according to the netlist. Next, in step S740, the routing paths are obtained according to the placement and the netlist. If there is no congestion or violation, the IC is implemented (or fabricated) according to the placement and the routing paths (step S750). If there is congestion or violation, the automatic place and route (APR) procedure is performed again (steps S730 and S740) so as to generate a new placement for the gates with the corresponding routing paths for the IC.

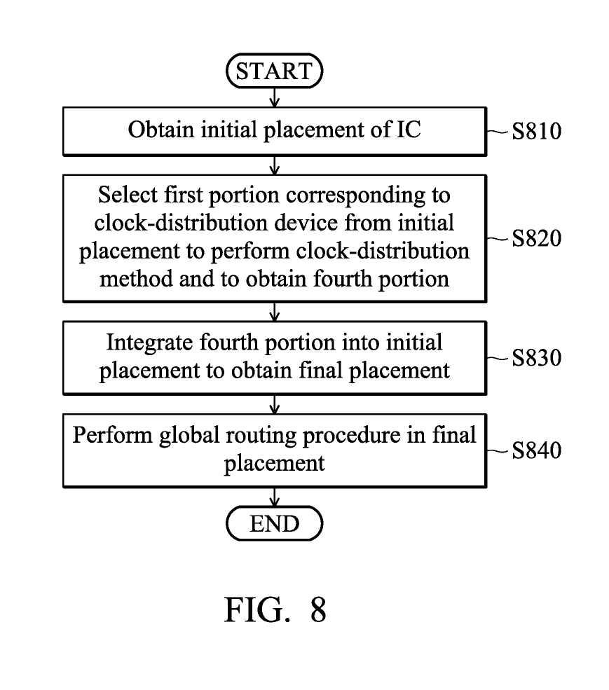

FIG. 8 shows a method for arranging a clock-distribution device 10 of an integrated circuit (IC) according to an embodiment of the invention, wherein the method of FIG. 8 is performed by a computer capable of operating an electronic design automation (EDA) tool. First, in step S810, a processor of the computer obtains an initial placement of the IC. The initial placement can be displayed in a graphical user interface (GUI). The initial placement includes a first portion corresponding to the clock-distribution device 10, a second portion corresponding to a plurality of modules and a third portion corresponding to a clock-generation device 30. The second portion includes the complete layout of the modules, and the third portion includes the complete layout of the clock-generation device 30. The first portion includes the input port 140, and the output ports 150 of the clock-distribution device 10. In some embodiments, the first portion further includes some buffers 130 of the clock-distribution device 10. In some embodiments, the first portion includes a profile or contour of the clock-distribution device 10. Specifically, the first portion does not include the complete layout of the clock-distribution device 10. For example, no clock mesh 120 or no mesh driver 160 is present in the first portion. In some embodiments, the size and shape of the first portion of the clock-distribution device 10 is determined according to the routing resource required for clock mesh routing and the register distribution of the registers 20 within the second portion. For example, the pin assignment of the output ports 150 is determined according to the registers 20 of the modules in the second portion, and the pin assignment of the input port 140 is determined according to the clock-generation device 30 in the third portion.

In step S820, the processor selects the first portion corresponding to the clock-distribution device from the initial placement to perform the clock-distribution method of FIG. 3, so as to implement the clock-distribution device 10 individually and additionally. Specifically, the clocks are distributed in the clock-distribution device 10 in step S820. As described above, the clock-distribution device 10 is capable of distributing a plurality of clock signals to the modules according to the clock signal from the clock-generation device 30, and each module includes one or more registers 20. In other words, the clock-distribution device is cut out (or taken out) from the initial placement of the IC. In some embodiments, the clock gates 110, the clock mesh 120, the buffer 130, the input port 140 and the output ports 150 within the clock-distribution device 10 are placed and routed by the processor, so as to obtain a fourth portion including the complete layout of the clock-distribution device 10, i.e. the configuration of the clock-distribution device 10 is considered as a standalone design. Thus, the fourth portion includes the complete layout of the clock-distribution device 10. The clock mesh 120 or the mesh drivers 160 are present in the fourth portion. Next, in step S830, the processor integrates the fourth portion into the initial placement to obtain a final placement for IC, i.e. the fourth portion is placed into the location of the first portion of the initial placement. Specifically, the first portion of the initial placement is replaced with the fourth portion, so as to obtain the final placement.

In step S840, the processor performs a global routing procedure in the final placement of the IC, so as to connect the output ports 150 of the clock-distribution device 10 to a plurality of input ports of the modules via a plurality of first routing paths and to connect the input port 140 of the clock-distribution device 10 to an output port of the clock-generation device via a second routing path. Therefore, the clock-distribution device 10 receives the clock signal from the clock-generation device 30 through the second routing path. Furthermore, the clock-distribution device 10 provides the clock signals corresponding to the clock signal from the clock-generation device 30 to the corresponding modules through the first routing paths. In some embodiments, each first routing path has a shortest distance achieved from the corresponding output port 150 to the corresponding register 20. As described above, if there is no congestion or violation, the IC is implemented (or fabricated) according to the final placement and the routing paths.

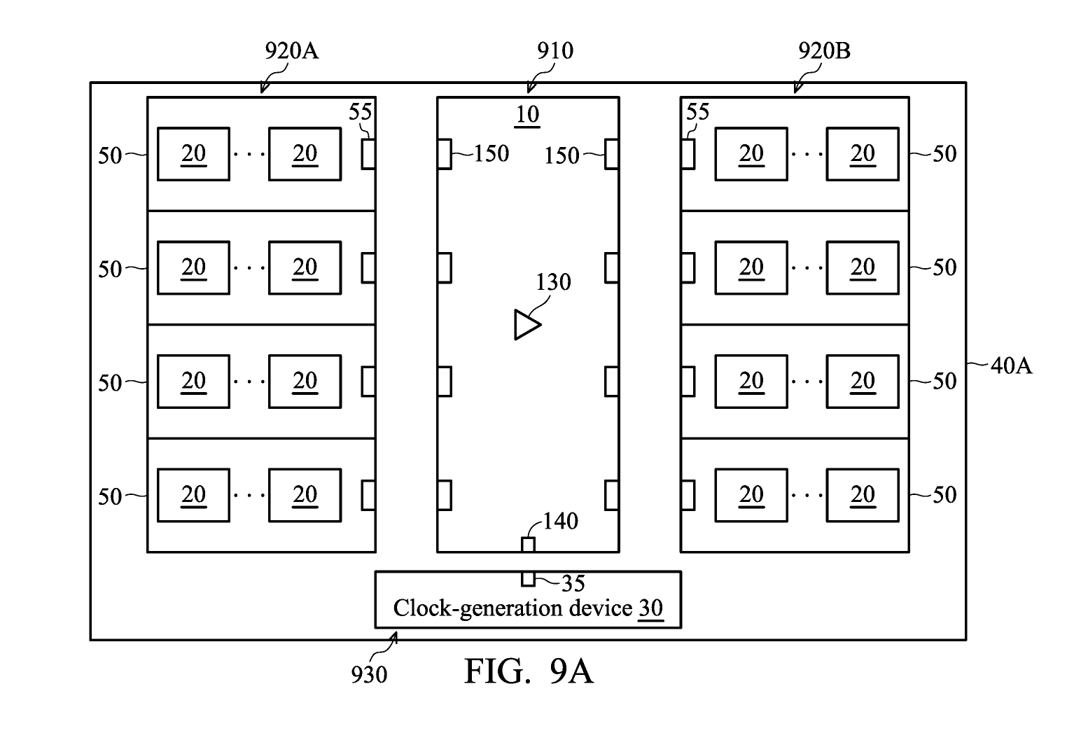

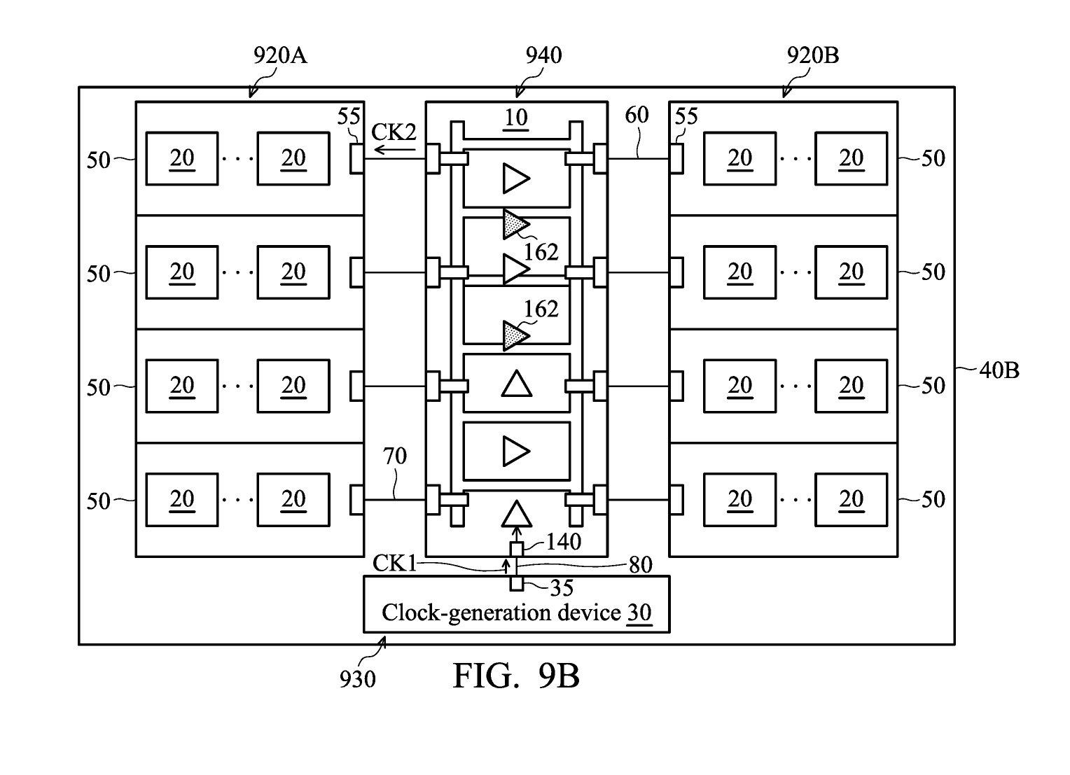

FIG. 9A shows an example illustrating an initial placement 40A of an IC obtained in step S810 of the method of FIG. 8. The initial placement 40A includes a first portion 910 corresponding to the clock-distribution device 10, the second portions 920A and 920B corresponding to a plurality of modules, and a third portion 930 corresponding to a clock-generation device 30. In FIG. 9A, the second portion 920A is arranged on the left side of the first portion 910, and the second portion 920B is arranged on the right side of the first portion 910. Furthermore, the third portion 930 is arranged at the bottom of the first portion 910. Each of the second portions 920A and 920B includes a plurality of modules 50. In some embodiments, the registers 20 of the modules 50 have the same layout configuration. In the first portion 910, only some devices and/or interfaces are present, such as the buffers 130, the input port 140, and the output ports 150 of the clock-distribution device 10.

FIG. 9B shows an example illustrating a final placement 40B and the routing paths of the IC obtained in step S830 of the method of FIG. 8. The final placement 40B includes a fourth portion 940 corresponding to the clock-distribution device 10, the second portions 920A and 920B corresponding to a plurality of modules, and a third portion 930 corresponding to a clock-generation device 30. As described above, the fourth portion 940 is obtained by selecting the first portion 910 from the initial placement 40A and performing the clock-distribution method of FIG. 3 on the first portion 910 of the clock-distribution device 10.

As described above, the clock-generation device 30 is capable of providing a clock signal CK1, and a clock-distribution device 10 is capable of distributing a plurality of clock signals CK2 to a plurality of modules 50 according to the clock signal CK1 from the clock-generation device 30. Furthermore, the clock skew of each clock signal CK2 is controlled by the clock-distribution device 10. Each module 50 includes one or more registers 20. In some embodiments, the modules 50 have the same layout configuration. Furthermore, each module 50, the clock-distribution device 10, and the clock-generation device 30 are independent modules in the layout, and the configuration of the independent module can be adjusted individually. In the clock-distribution device 10, a portion of the output ports 150 are assigned on the right side of the clock-distribution device 10, and the remaining output ports 150 are assigned on the left side of the clock-distribution device 10. Each output port 150 assigned on the right side is coupled to an input port 55 of the corresponding module 50 via a routing line 60, so as to provide the clock signal CK2 to the corresponding module 50, and the corresponding module 50 is disposed on the right side of the clock-distribution device 10. Moreover, each output port 150 assigned on the left side is coupled to an input port 55 of the corresponding module 50 via a routing line 70, and the corresponding module 50 is disposed on the left side of the clock-distribution device 10. In some embodiments, the output ports 150 are symmetrically assigned in the opposite sides of the clock-distribution device 10. In some embodiments, the output ports 150 are assigned in the same side of the clock-distribution device 10. Furthermore, the input port 140 assigned at the bottom side is coupled to an input port 55 of the corresponding module 50 via a routing line 80. Specifically, the clock-distribution device 10 is surrounded by the modules 50 and the clock-generation device 30. Furthermore, the configurations of the output ports 150 and the shape of the clock-distribution device 10 are determined according to the positions of the modules 50.

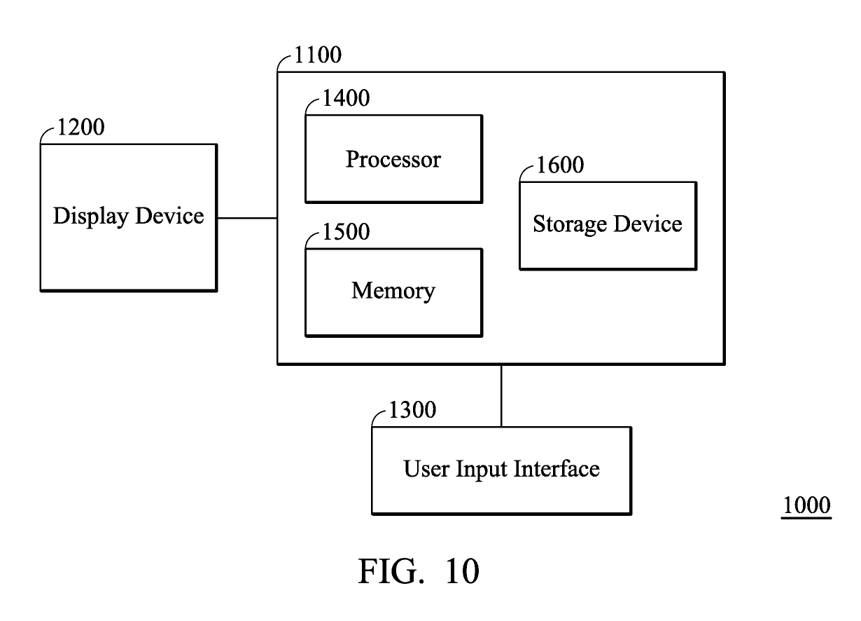

FIG. 10 shows a computer system 1000 according to an embodiment of the invention. The computer system 1000 includes a computer 1100, a display device 1200 and a user input interface 1300, wherein the computer 1100 includes a processor 1400, a memory 1500, and a storage device 1600. The computer 1100 is coupled to the display device 1200 and the user input interface 1300, wherein the computer 1100 is capable of operating an electronic design automation (EDA) tool. Furthermore, the computer 1100 is capable of receiving instructions input from the user input interface 1300 and displaying the placement and routing of the IC on the display device 1200. In one embodiment, the display device 1200 is a GUI for the computer 1100. Furthermore, the display device 1200 and the user input interface 1300 can be implemented in the computer 1100. The user input interface 1300 may be a keyboard, a mouse, and so on. In the computer 1100, the storage device 1600 can store the operating systems (OSs), applications, and data comprising input required by the applications and/or output generated by the applications. The processor 1400 of the computer 1100 can perform one or more operations (either automatically or with user input) in any method that is implicitly or explicitly described in this disclosure. For example, during operation, the processor 1400 can load the applications of the storage device 1600 into the memory 1500, and then the applications can be used by the user to create, view, and/or edit a placement for a circuit design.

The data structures and code described in this disclosure can be partially or fully stored on a computer-readable storage medium and/or a hardware module and/or hardware apparatus. A computer-readable storage medium includes, but is not limited to, volatile memory, non-volatile memory, magnetic and optical storage devices such as disk drives, magnetic tape, CDs (compact discs), DVDs (digital versatile discs or digital video discs), or other media, now known or later to be developed, that are capable of storing code and/or data. Hardware modules or apparatuses described in this disclosure include, but are not limited to, application-specific integrated circuits (ASICs), field-programmable gate arrays (FPGAs), dedicated or shared processors, and/or other hardware modules or apparatuses now known or later to be developed.

The methods and processes described in this disclosure can be partially or fully embodied as code and/or data stored in a computer-readable storage medium or device, so that when a computer system reads and executes the code and/or data, the computer system performs the associated methods and processes. The methods and processes can also be partially or fully embodied in hardware modules or apparatuses, so that when the hardware modules or apparatuses are activated, they perform the associated methods and processes. Note that the methods and processes can be embodied using a combination of code, data, and hardware modules or apparatuses.

Although embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A method for arranging a clock-distribution device of an integrated circuit (IC), comprising:
obtaining an initial placement of the IC, wherein the initial placement comprises a first portion corresponding to a clock-distribution device, a second portion corresponding to a plurality of modules, and a third portion corresponding to a clock-generation device, wherein the clock-distribution device is configured to distribute a plurality of first clock signals to the modules according to a second clock signal from the clock-generation device;
selecting the first portion from the initial placement;
distributing clocks within the selected first portion to obtain a fourth portion of the clock-distribution device; and
placing the fourth portion in the initial placement to replace the first portion and to obtain a final placement of the IC,
wherein each of the modules has an input port corresponding to the individual first clock signal, and the clock-generation device has an output port corresponding to the second clock signal.

2. The method as claimed in claim 1, further comprising:
performing a routing procedure in the final placement, so as to connect a plurality of output ports of the clock-distribution device to the input ports of the modules via a plurality of first routing paths and to connect an input port of the clock-distribution device to the output port of the clock-generation device via a second routing path.

3. The method as claimed in claim 2, further comprising:
fabricating the IC according to the final placement and the routing paths.

4. The method as claimed in claim 2, wherein in the fourth portion, a portion of the output ports of the clock-distribution device are assigned on a first side of the clock-distribution device, and the remaining output ports are assigned on a second side of the clock-distribution device, wherein the first side is opposite to the second side in the clock-distribution device.

5. The method as claimed in claim 4, wherein in the fourth portion, the input port of the clock-distribution device is assigned on a third side of the clock-distribution device, wherein the third side is different from the first and second sides in the clock-distribution device.

6. The method as claimed in claim 1, wherein each of the modules comprises at least one register corresponding to the first clock signal, and configurations of the output ports and shape of the clock-distribution device are determined according to positions of the modules.

7. The method as claimed in claim 1, wherein the step of distributing the clocks within the selected first portion to obtain the fourth portion of the clock-distribution device further comprises:
arranging a clock mesh to distribute the first clock signals for the modules uniformly; and
arranging at least one mesh driver to transmit and/or divide the second clock signal, wherein the mesh driver connects to the clock mesh to drive the clock mesh.

8. The method as claimed in claim 7, wherein the step of distributing the clocks within the selected first portion to obtain the fourth portion of the clock-distribution device further comprises:
determining number of registers of the modules and a transition of the second clock signal before the clock mesh and the mesh driver are arranged.

9. The method as claimed in claim 8, wherein the clock mesh and the mesh driver are arranged based on the number of registers and the transition of the second clock signal.

10. The method as claimed in claim 7, wherein the step of distributing the clocks within the selected first portion to obtain the fourth portion of the clock-distribution device further comprises:
arranging at least one buffer between the mesh driver and the clock-generation device to transmit the second clock signal to the mesh driver before the clock mesh and the mesh driver are arranged.

11. The method as claimed in claim 10, wherein the step of distributing the clocks within the selected first portion to obtain the fourth portion of the clock-distribution device further comprises:
arranging a plurality of clock gates to be coupled to the modules via a plurality of output ports before the at least one buffer is arranged.

12. The method as claimed in claim 7, wherein the step of distributing the clocks within the selected first portion to obtain the fourth portion of the clock-distribution device further comprises:
routing the clock mesh after the clock mesh and the mesh driver are arranged.

13. The method as claimed in claim 12, wherein the step of distributing the clocks within the selected first portion to obtain the fourth portion of the clock-distribution device further comprises:
simulating timing of the first clock signals after the clock mesh is routed.

14. A method for arranging a clock-distribution device of an integrated circuit (IC), comprising:
obtaining an initial placement of the IC, wherein the initial placement comprises a profile of a clock-distribution device, a first layout of a plurality of modules, and a second layout of a clock-generation device, wherein the clock-distribution device is configured to distribute a plurality of first clock signals to the modules according to a second clock signal from the clock-generation device;
cutting out the profile of a clock-distribution device from the initial placement;
distributing clocks within the clock-distribution device to arrange a clock mesh and at least one mesh driver in the clock-distribution device, to obtain a third layout of the clock-distribution device; and
integrating the first layout of the modules, the second layout of the clock-generation device, and the third layout of the clock-distribution device to obtain a final placement of the IC,
wherein each of the modules has an input port corresponding to the individual first clock signal, and the clock-generation device has an output port corresponding to the second clock signal.

15. The method as claimed in claim 14, further comprising:
performing a routing procedure in the final placement, so as to connect a plurality of output ports of the clock-distribution device to the input ports of the modules via a plurality of first routing paths and to connect an input port of the clock-distribution device to the output port of the clock-generation device via a second routing path; and
fabricating the IC according to the final placement and the routing paths.

16. The method as claimed in claim 14, wherein the step of distributing clocks within the clock-distribution device to arrange the clock mesh and the mesh driver in the clock-distribution device, to obtain the third layout of the clock-distribution device further comprises:
arranging the clock mesh to distribute the first clock signals for the modules uniformly; and
arranging the mesh driver to transmit and/or divide the second clock signal, wherein the mesh driver connects to the clock mesh to drive the clock mesh.

17. The method as claimed in claim 16, wherein the step of distributing clocks within the clock-distribution device to arrange the clock mesh and the mesh driver in the clock-distribution device, to obtain the third layout of the clock-distribution device further comprises:
determining number of registers of the modules and a transition of the second clock signal before the clock mesh and the mesh driver are arranged.

18. The method as claimed in claim 17, wherein the clock mesh and the mesh driver are arranged based on the number of registers and the transition of the second clock signal.

19. The method as claimed in claim 14, wherein the step of distributing clocks within the clock-distribution device to arrange the clock mesh and the mesh driver in the clock-distribution device, to obtain the third layout of the clock-distribution device further comprises:
arranging at least one buffer between the mesh driver and the clock-generation device to transmit the second clock signal to the mesh driver before the clock mesh and the mesh driver are arranged.

20. The method as claimed in claim 19, wherein the step of distributing clocks within the clock-distribution device to arrange the clock mesh and the mesh driver in the clock-distribution device, to obtain the third layout of the clock-distribution device further comprises:
arranging a plurality of clock gates to be coupled to the modules via a plurality of output ports before the at least one buffer is arranged.
